(19) United States
(12) Patent Application Publication
(10) Pub. No.: US 2018/0240376 A1
(43) Pub. Date: Aug. 23, 2018

(54) PACKAGING LABEL AND METHOD FOR LABELLING A PACKAGE

(71) Applicants: FONDAZIONE ISTITUTO ITALIANO DI TECNOLOGIA, Genova (IT); POLITECNICO DI MILANO, Milano (IT)

(72) Inventors: Mario CAIRONI, Milano (IT); Marco CARVELLI, Milano (IT); Antonio IACCHETTI, Castellone (IT); Giorgio DELL'ERBA, Bari (IT)

(73) Assignees: FONDAZIONE ISTITUTO ITALIANO DI TECNOLOGIA, Genova (IT); POLITECNICO DI MILANO, Milano (IT)

(21) Appl. No.: 15/574,033

(22) PCT Filed: May 19, 2016
(86) PCT No.: PCT/EP2016/061324

§ 371 Date: Nov. 15, 2017

(30) Foreign Application Priority Data
May 20, 2015 (IT) 102015000016245

(51) Int. Cl. G09F 3/20

(52) U.S. Cl. CPC G09F 3/208; H01L 31/054

(57) ABSTRACT

Packaging label (1) comprising a substrate (10), a display (6) placed above the substrate (10), a control module (4) placed in electrical contact with the display (6) and adapted to control the operation of said display (6), at least one photovoltaic module (2) placed above the substrate (10) and next to the display (6) and predisposed to supply the display (6) and the control module (4); wherein the photovoltaic module (2), the control module (4) and the display (6) are printed on the substrate (10) using a printing ink mixed with dopants.

The present invention relates to a packaging label and to a method for labelling a package.

In the packaging industry labels with fixed graphics are known, i.e. bearing a predetermined message, which may be adhesive or printed directly onto the packaging, for example a plastic or glass bottle.

However, such labels have the disadvantage of being able to produce only one message (e.g. product name, list of ingredients, promotional message), therefore for many commercial products, it is necessary to use a plurality of different labels, each dedicated to specific contents.

In the field of electronics on plastic, dynamic labels are also known, provided with a display for displaying a plurality of different messages, such as, for example, a promotional message, the expiry date and/or the ingredients of the packaged product. However, such labels are not fully comprised of materials compatible with recycling (including the display) and the production process is not compatible with high performance printing or with direct printing on the packaging container. Furthermore, such labels must be self-supplied and not even the supply unit satisfies the above indicated requirements.

Therefore, there is a need to find innovative solutions to the problem of “dynamically” labelling packaged products, mainly for marketing and advertising purposes.

The object of the invention is therefore to propose a dynamic label able to progressively change the contents displayed, which may be directly printed and/or integrated onto the packaging and which is compatible with current packaging production processes, by adding to the packaging itself a negligible cost in order to be economically sustainable.

A further object of the invention is that of proposing an easily recyclable label. These and other objects are reached with a label whose characteristics are defined in claim 1.

Particular embodiments form the subject matter of the dependent claims, whose contents are to be considered an integral part of the present description.

Further characteristics and advantages of the invention will appear from the following detailed description, given by way of non-limitative example, with reference to the appended drawings, in which:

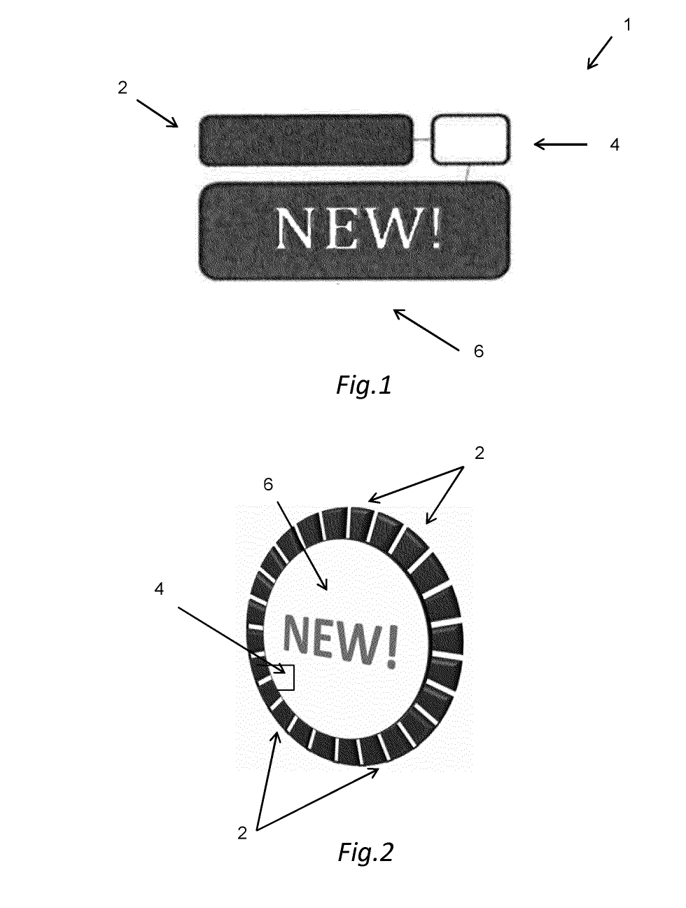

FIG. 1 is a schematic front view of a label according to the present invention;

FIG. 2 illustrates a front view of an embodiment of the label of FIG. 1;

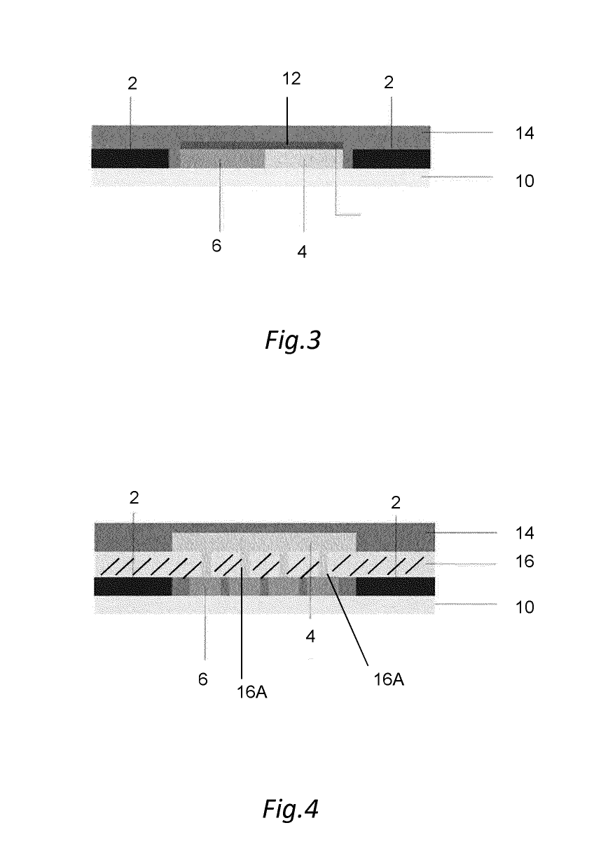

FIG. 3 shows a sectional view of the label of FIG. 1;

FIG. 4 shows a variation of the label according to the present invention; and

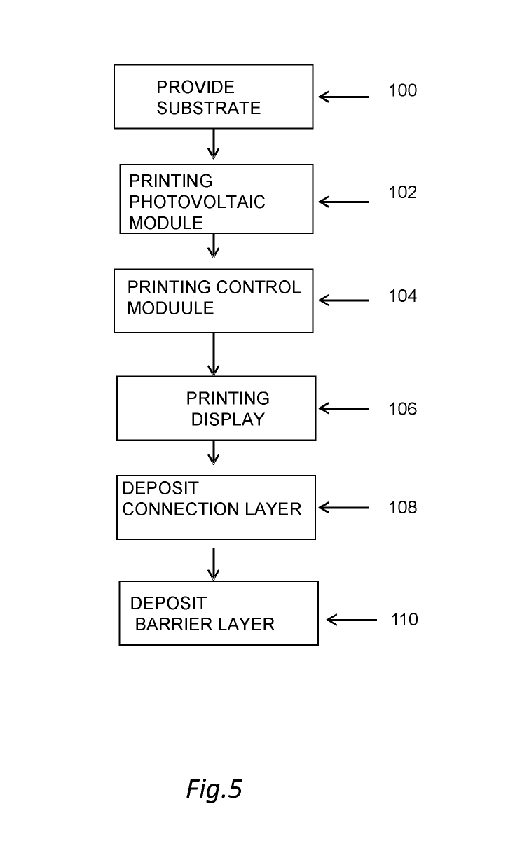

FIG. 5 shows a block diagram of the operations of the method for obtaining a label according to the present invention.

In summary, a label according to the present invention is fully recyclable, can be printed with high performance printing processes either on plastic or on paper or directly on plastic packaging, for example PET, and can be used with the current packaging industry standards. The label according to the present invention also integrates a source of independent energy.

FIG. 1 shows a schematic front view of a label 1 according to the present invention. Such label 1 comprises at least a photovoltaic source 2 adapted to supply a control module 4 and a display 6 bearing a message.

The photovoltaic source 2 is a photovoltaic module known in itself, which preferably uses a bulk heterojunction organic technology. Alternatively, the photovoltaic source is not organic, being, for example, a photovoltaic source based on quantum dots or hybrid perovskite. The photovoltaic module 2 can be printed, in a known way, on a plastic substrate, for example, polyethylene terephthalate (PET) having a thickness preferably comprised in the interval 1 μm-100 μm.

FIG. 2 shows a front view of an embodiment of the label 1 in which there are a plurality of photovoltaic modules 2 arranged along a circumference, the display 6 corresponding to the area containing the message and the control module 4 being next to the display 6 (alternatively, the control module 4 is positioned below the display 6 as described in detail below).

Below, with reference to FIGS. 3 and 4, the process will be described for obtaining a label according to the present invention, the block diagram of which is shown in FIG. 5. Such a procedure starts with a first step 100 of providing a substrate 10, preferably of the type described above. Such substrate 10 may be transparent or opaque. In an embodiment of the present invention, the label is printed directly on the packaging (e.g. a plastic bottle or paper box), in which case the substrate is the surface of the packaging itself. Alternatively the substrate could be made of (or including) other materials, e.g. metal foils, rubber, self-adhesive substrate, tattoo paper.

FIG. 3 shows a sectional view of the label 1 in which the substrate 10 is present, preferably a plastic sheet or bottle, onto which, in step 102 the photovoltaic module is printed. Between the photovoltaic modules 2 in steps 104 and 106 the control module 4, preferably comprising at least a low power supply thin film transistor, and the display 6 are printed, respectively, the latter preferably provided in the form of a layer of electrically addressable material, e.g. and electrochromic material. Alternatively the layer could be made of any other electrically addressable material, e.g. electroluminescent material. A fundamental limit connected with organic electronic printing (steps 102-106 described above) on thin (10-200 μm) and ultrathin (less than 10 μm) plastic supports is connected with the maximum temperature of the printing process. Typically, to perform such printing, thermal heating processes are required, which are not compatible with the thin layer of plastic substrate used in the packaging, since such a layer would be heat sensitive. The optimisation of the organic electronic printing process is closely connected with the annealing processes, which typically require temperatures of over 100° C., necessary for optimising the performance of the printed devices, for example, improving the mobility of charge carriers, de-absorbing contaminants and obtaining the desired morphology of the support layer.

In the printing operations 102-106 described above, ink is used which is in itself known, to which, before performing the printing itself, dopants are added, preferably precursors of benzimidazole and benzimidazoline or caesium or lithium salts.

Thanks to the use of these particular chemical dopants, optimised electronics are obtained, printed directly at room temperature or however at low temperatures compatible with the substrate 10 (preferably lower than 70° C.), in which only the evaporation of the ink solvent is required.

The control module 4 is provided to send control signals to the display 6 so that predetermined messages are shown on the display 6.

The control module 4 and the display 6 are in electrical contact with the photovoltaic module 2 for allowing its supply by the latter.

Above the control module 4 and the display 6, in step 108, an electrical lateral interconnecting layer 12 is deposited, preferably of ion-gel or solid electrolyte type, which allows the control module 4 to perform a low voltage control of the display 6, i.e. allowing the control module 4 to send control signals to the display 6.

Alternatively, the control module 4 is provided through at least one thin film transistor comprising semiconductor metal oxides such as, for example, ZnO, IZO, IGZO.

Finally, in step 110, on top of all the underlying layers, a barrier layer 14 is deposited, preferably oxide/polymer multilayer, for example silica and alumina for the inorganic layer and EVA, ETFE, PET or PEN for the organic layer, so as to protect the underlying layers from oxygen and water vapour.

FIG. 4 shows a variation of the invention wherein similar layers are indicated with the same reference numbers. In this variation, only the display 6 is placed between two photovoltaic modules 2 above the substrate 10 and not also the control module 4. Above the photovoltaic modules 2 and the display 6 an insulating layer 16 is first deposited, having a predetermined pattern, i.e. a plurality of holes 16a placed in correspondence of the display 6 and subsequently the control module 4 is deposited which, through the holes 16a, comes into contact with the display 6 below. Finally, above the control module 4 the barrier layer 14 is deposited.

Therefore, in this embodiment, during use, there will be the front display 6 and the control module 4 behind it.

The label 1 according to the present invention is recyclable because all the electronic components are made with plastic electronic materials or easily separable from plastic (metallisations of silver or other metals).

The active label 1 is also recyclable because the materials of which each of its components are comprised, i.e. the photovoltaic module 2, the control module 4 and the display 6 are characterised by a low melting temperature (comprised between 200 and 400° C.). In this way, any traces of non-plastic materials (metals, metal oxides, etc.) present in the label 1 can be removed by filtering, in a known way, through techniques for the purification of recycled plastic.

Naturally, various modifications to the principle of the invention, the embodiments and construction details may be possible, according to what is described and disclosed merely by way of non-limitative example, without departing from the scope of the present invention, as defined by the appended claims.

1-15. (canceled)

16. A packaging label comprising:
a flexible substrate;
a display printed above the substrate, the display comprising an electrically addressable layer of printable ink;
a control module printed above the substrate, in electrical contact with the display and arranged to control the operating of such display the control module including a layer comprising at least one printing ink mixed with dopants; and
at least a photovoltaic module printed above the substrate and next to the display and arranged to supply the display and the control module, the photovoltaic module including a layer comprising at least one printing ink mixed with dopants.

17. The label according to claim 16, wherein the substrate is made of at least one material selected from the following: plastic, paper, metal foils, rubber, self-adhesive substrate, tattoo paper.

18. The label according to claim 16, wherein the display comprises a layer of electrochromic printable ink.

19. The label according to claim 16, wherein the substrate has a thickness between 1 and 100 μm.

20. The label according to claim 16, wherein the dopants include benzimidazole or benzimidazoline or caesium or lithium salts.

21. The label according to claim 16, wherein the electric contact between the control module and the display comprises an inter-connecting layer of ion-gel or solid electrolyte, the inter-connecting layer having also the function of Ion reservoir for the electrochromic display and/or gate medium for the transistors in the control unit.

22. The label according to claim 16, wherein the control module comprises a low-voltage organic thin layer transistor.

23. The label according to claim 16, wherein the control module comprises at least a thin film transistor comprising semiconductor metal oxides.

24. The label according to claim 16, comprising a barrier layer placed above the control module.

25. The label according to claim 16, comprising an insulating layer placed above the display and on which the control module is placed, the insulating layer having a plurality of holes placed in correspondence of the display and arranged to allow the electric contact between the display and the control module.

26. A method of obtaining a packaging label for packaging, the method comprising:
printing on a substrate at least one photovoltaic module;
printing, next to the photovoltaic module, respectively, a control module and a display;
depositing above the control module and the display an electrical lateral interconnecting layer arranged to allow the control module to control the display; and
wherein the printing steps of the photovoltaic module, the control module and the display comprise the step of mixing a printing ink with dopants.

27. The method according to claim 26, comprising the step of a barrier layer, arranged to protect the underlying layers.

28. The method according to claim 26, comprising depositing an insulating layer above the display so as to place the control module above the insulating layer, the insulating layer having a plurality of holes placed in correspondence of the display and arranged to allow the display to electrically contact the control module.

29. The method of labelling a package of claim 26, wherein the substrate is the surface of the package.

30. A packaging comprising a label printed with the method of claim 29.
